(19) United States
(12) Patent Application Publication
(10) Pub. No.: US 2013/0093991 A1
(43) Pub. Date: Apr. 18, 2013

(54) Backplane of Backlight Module, Backlight Module and LCD Device

(71) Applicants: Yicheng Kuo, Shenzhen (CN); Gege Zhou, Shenzhen (CN)

(72) Inventors: Yicheng Kuo, Shenzhen (CN); Gege Zhou, Shenzhen (CN)

(21) Appl. No.: 13/378,994

(22) PCT Filed: Dec. 13, 2011
(86) PCT No.: PCT/CN2011/083872

§ 371 Date: Dec. 16, 2011

(30) Foreign Application Priority Data
Oct. 12, 2011 (JP) 201110308489.5

(51) Int. Cl. G02F 1/1333; G09F 13/04; H05K 7/20

(52) U.S. Cl. 349/161; 361/709; 362/97.1

(57) ABSTRACT

The present invention discloses a backplane of a backlight module, a backlight module and an LCD device. The backplane of the backlight module comprises a heatsink plate with good heat dispersion and a low-cost supporting plate connected with the heatsink plate, wherein the heat conductivity of the heatsink plate is larger than that of the supporting plate. In the present invention, metal with good heat dispersion and common material with low cost are respectively adopted and joined according to different radiating areas of the backlight module; then, the heat dispersion is ensured and meanwhile, the cost is reduced.

### TECHNICAL FIELD

The present invention relates to the field of liquid crystal displays, and more particularly to a backplane of a backlight module, a backlight module and a liquid crystal display (LCD) device.

### BACKGROUND

An LCD device includes a display panel and a backlight module for providing a light source to the display panel. The bottom of the backlight module is provided with a backplane for supporting internal devices and sealing the module and providing necessary protection. The existing backplane of the backlight module is generally made of the same material; the material used is an aluminum plate, an iron plate or plastics. If the whole backplane is made of the iron plate, a radiating element shall be added, causing increase of cost; if the whole backplane is made of the aluminum plate, the radiating element is not added and used; although heat conduction effect of the aluminum plate is better than that of the iron plate, the aluminum plate has high cost and also increases the cost.

### SUMMARY

The aim of the present invention is to provide a backplane with good heat dispersion and low cost of a backlight module, a backlight module and an LCD device.

The aim of the present invention is achieved by the following technical schemes.

A backplane of a backlight module. The backplane of the backlight module comprises a heatsink plate and a supporting plate connected with the heatsink plate, wherein the heat conductivity of the heatsink plate is larger than that of the supporting plate.

Preferably, the heatsink plate and the supporting plate are both made of metal material. Because both of plates are made of metal, more varied connection modes can be provided; moreover, the strength is higher.

Preferably, the shapes and the areas of the heatsink plate and the supporting plate keep consistent. In the technical scheme, the heatsink plate and the supporting plate can be put into the same cover die and formed by stamping during production; then, the processing steps are reduced, the production efficiency is enhanced, and the production cost is reduced; in addition, the utilization of dies is also reduced, saving the cost of the dies.

Preferably, the heatsink plate and the supporting plate are fixed in a mode of riveting or screw connection. This is a concrete example of the heatsink plate and the supporting plate.

Preferably, the heatsink plate and the supporting plate are fixed in a mode of bonding by super glue. This is another concrete example of the heatsink plate and the supporting plate.

Preferably, the heatsink plate and the supporting plate are fixed in a mode of lock seaming; the heatsink plate and the supporting plate are folded in the joint to form clamping slots and clamping plates; the clamping plate of the heatsink plate is embedded into the clamping slot of the supporting plate; meanwhile, the clamping plate of the supporting plate is also embedded into the clamping slot of the heatsink plate to form the lock seaming connection. This is a third concrete example of the heatsink plate and the supporting plate. In the example, no other fixing material is used, thereby reducing the assembly steps and enhancing the assembly efficiency.

Preferably, the heatsink plate is arranged in the area of an LED lamp source fixing device of the backlight module. An LED is a major radiating device of the backlight module; Generally, the LED is fixed on the LED lamp source fixing device such as aluminum extrusion and the like; thus, the heatsink plate is arranged according to the area of the LED lamp source fixing device, so that the pertinence is higher, the area of the heatsink plate is further reduced, and the cost is reduced.

Preferably, the LED lamp source fixing device of the backlight module is an aluminum extrusion; the heatsink plate comes into contact with the aluminum extrusion. In the technical scheme, the heat can be passed from the aluminum extrusion to the heatsink plate in a heat conducting mode, and then can be dispersed to the outside air through the heatsink plate.

A backlight module comprises the aforementioned backplane of a backlight module.

An LCD device comprises the aforementioned backlight module.

Discovered through research, the backlight module does not uniformly radiate; only a part of the backplane performs a radiation action and the other part performs a supporting action instead of the radiation action; for the radiating part of the backplane, the metal with good heat dispersion is needed; for the supporting part of the backplane, only common material with certain strength is needed. In the present invention, the metal with good heat dispersion and the common material with low cost are respectively adopted and joined according to different radiating areas of the backlight module; then, the heat dispersion is ensured and meanwhile, the cost is reduced.

### BRIEF DESCRIPTION OF FIGURES

FIG. 1 is a schematic diagram of a heatsink plate and a supporting plate which are separated in the present invention;

FIG. 2 is a schematic diagram of a heatsink plate and a supporting plate which are joined in the present invention;

FIG. 3 is a schematic diagram of simultaneously processing a heatsink plate and a supporting plate through the same die in the present invention;

FIG. 4 is a schematic diagram of fixing a heatsink plate and a supporting plate by a manufacturing process of a riveting technology in the present invention;

FIG. 5 is a schematic diagram of fixing a heatsink plate and a supporting plate in a non-rivet riveting mode in the present invention;

FIG. 6 is a schematic diagram of fixing a heatsink plate and a supporting plate in a riveting mode of rivets in the present invention;

FIG. 7 is a schematic diagram of fixing a heatsink plate and a supporting plate in a bonding mode by super glue in the present invention;

FIG. 8 is a schematic diagram of fixing a heatsink plate and a supporting plate in a screw connection mode in the present invention;

FIG. 9 is a schematic diagram of fixing a heatsink plate and a supporting plate in a lock seaming connection mode in the present invention;

Wherein: 1. heatsink plate; 2. supporting plate; 3. rivet; 4. super glue; 5. screw.

### DETAILED DESCRIPTION

The present invention will further be described in detail in accordance with the figures and the preferred examples.

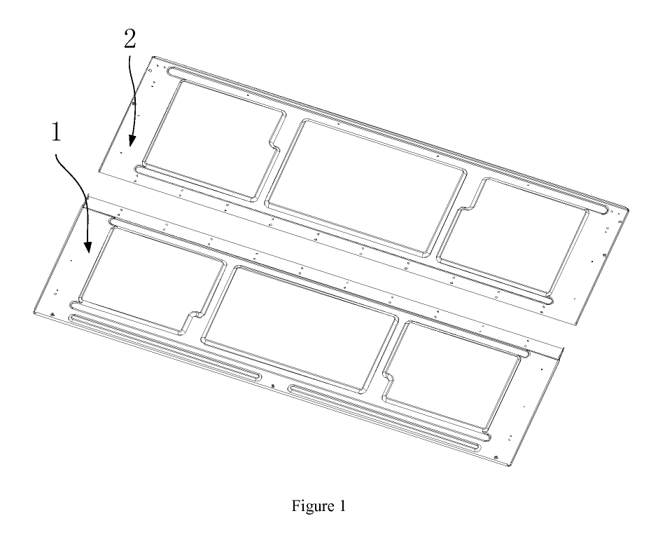

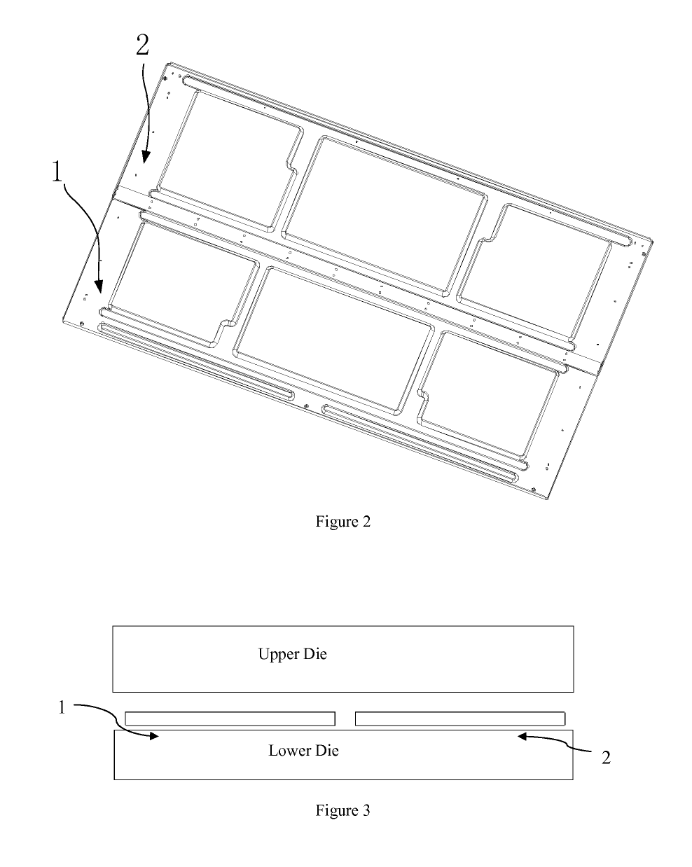

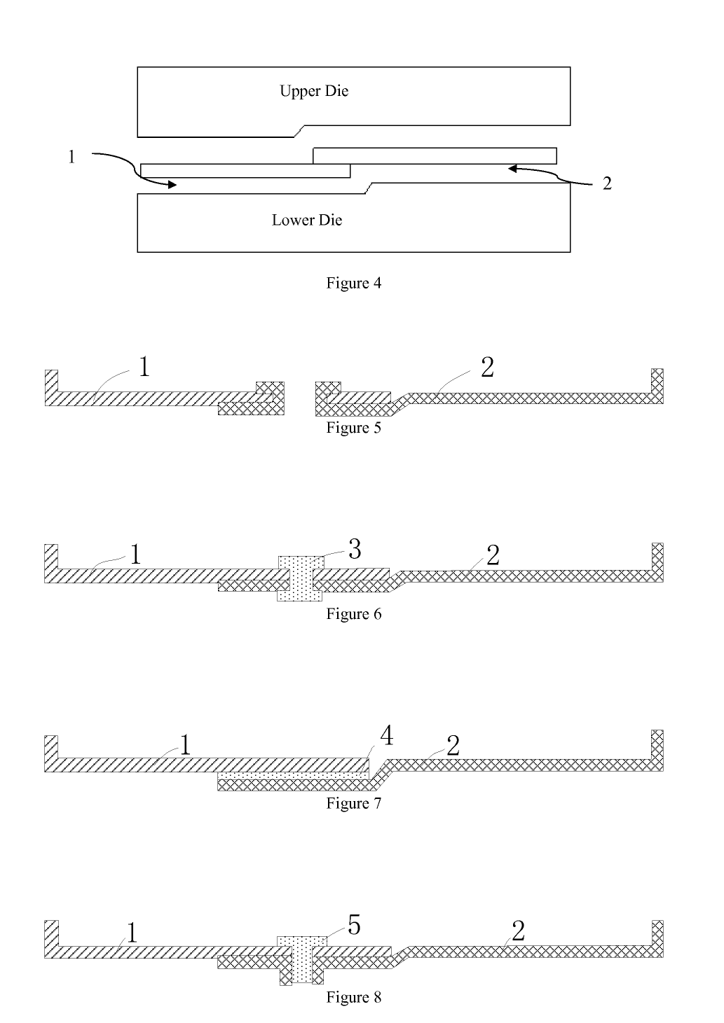

As shown in FIGS. 1 to 9, an LCD device comprises a backlight module; the bottom of the backlight module is provided with a backplane for supporting internal devices and sealing the module and providing necessary protection. The backplane of the backlight module comprises a heatsink plate 1 and a supporting plate 2 connected with the heatsink plate 1; the heat conductivity of the heatsink plate 1 is larger than that of the supporting plate 2; the heatsink plate 1 can be made of metal with good heat dispersion, such as aluminum and the like; the supporting plate 2 can be made of metal material of cheaper price, such as steel plates and the like, or low-cost material with certain strength, such as plastics and the like.

The heatsink plate 1 is arranged in the area of an LED lamp source fixing device of the backlight module. An LED is a major radiating device of the backlight module; Generally, the LED is fixed on the LED lamp source fixing device such as aluminum extrusion and the like; taking an aluminum extrusion as an example, the aluminum extrusion can be installed on the heatsink plate 1 of the backplane; then, the heat can be quickly passed from the aluminum extrusion to the heatsink plate 1 in a heat conducting mode, and can be dispersed to the outside air through the heatsink plate 1.

Further, the shapes and the areas of the heatsink plate 1 and the supporting plate 2 keep consistent. The heatsink plate 1 and the supporting plate 2 can be put into the same cover die and formed by stamping during production; then, the processing steps are reduced, the production efficiency is enhanced, and the production cost is reduced; in addition, the utilization of dies is also reduced, saving the cost of the dies.

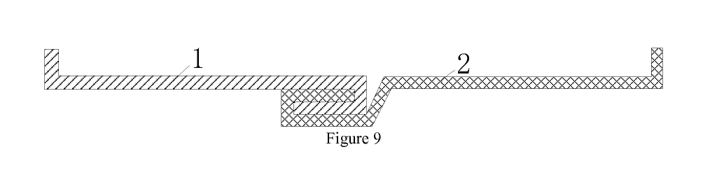

The heatsink plate 1 and the supporting plate 2 can be fixed in the modes of riveting (as shown in FIG. 5 and FIG. 6), bonding by super glue 4 (as shown in FIG. 7), a screw 5 connection (as shown in FIG. 8), lock seaming connection (as shown in FIG. 9) and the like; the riveting can include riveting without a rivet 3 (as shown in FIG. 5) and riveting with the rivet 3 (as shown in FIG. 6). The fixing mode of the present invention will be further explained below in the lock seaming mode:

As shown in FIG. 9, the heatsink plate 1 and the supporting plate 2 are fixed in the mode of lock seaming; the heatsink plate 1 and the supporting plate 2 are folded in the joint to form clamping slots and clamping plates; the clamping plate of the heatsink plate 1 is embedded into the clamping slot of the supporting plate 2; meanwhile, the clamping plate of the supporting plate 2 is also embedded into the clamping slot of the heatsink plate 1 to form the lock seaming connection. In the example, no other fixing material is used, thereby reducing the assembly steps and enhancing the assembly efficiency.

The present invention is described in detail in accordance with the above contents with the specific preferred examples. However, this invention is not limited to the specific examples. For the ordinary technical personnel of the technical field of the present invention, on the premise of keeping the conception of the present invention, the technical personnel can also make simple deductions or replacements, and all of which should be considered to belong to the protection scope of the present invention.

We claim:

1, A backplane of a backlight module, comprising: a heatsink plate and a supporting plate connected with the heatsink plate; the heat conductivity of said heatsink plate is larger than the heat conductivity of said supporting plate.

2, The backplane of the backlight module of claim 1, wherein said heatsink plate and said supporting plate are both made of metal material.

3, The backplane of the backlight module of claim 2, wherein the shapes and the areas of said heatsink plate and said supporting plate keep consistent.

4, The backplane of the backlight module of claim 1, wherein said heatsink plate and said supporting plate are fixed in a mode of riveting or a screw connection.

5, The backplane of the backlight module of claim 1, wherein said heatsink plate and said supporting plate are fixed in a mode of bonding by super glue.

6, The backplane of the backlight module of claim 1, wherein said heatsink plate and said supporting plate are fixed in a mode of lock seaming; said heatsink plate and said supporting plate are folded in the joint to form clamping slots and clamping plates; the clamping plate of said heatsink plate is embedded into the clamping slot of said supporting plate; meanwhile, the clamping plate of said supporting plate is also embedded into the clamping slot of said heatsink plate to form said lock seaming connection.

7, The backplane of the backlight module of claim 1, wherein said heatsink plate is arranged in the area of an LED lamp source fixing device of the backlight module.

8, The backplane of the backlight module of claim 2, wherein the LED lamp source fixing device of said backlight module is an aluminum extrusion; said heatsink plate comes into contact with said aluminum extrusion.

9, A backlight module, comprising the backplane of the backlight module of claim 1; said backplane of the backlight module comprises a heatsink plate and a supporting plate connected with the heatsink plate; the heat conductivity of said heatsink plate is larger than the heat conductivity of said supporting plate.

10, The backlight module of claim 9, wherein said heatsink plate and said supporting plate are both made of metal material.

11, The backlight module of claim 10, wherein, the shapes and the areas of said heatsink plate and said supporting plate keep consistent.

12, The backlight module of claim 9, wherein said heatsink plate and said supporting plate are fixed in a mode of riveting or a screw connection.

13, The backlight module of claim 9, wherein, said heatsink plate and said supporting plate are fixed in a mode of bonding by super glue.

14, The backlight module of claim 9, wherein said heatsink plate and said supporting plate are fixed in a mode of lock seaming; said heatsink plate and said supporting plate are folded in the joint to form clamping slots and clamping plates; the clamping plate of said heatsink plate is embedded into the clamping slot of said supporting plate; meanwhile, the clamping plate of said supporting plate is also embedded into the clamping slot of said heatsink plate to form said lock seaming connection.

15, The backlight module of claim 9, wherein, said heatsink plate is arranged in the area of an LED lamp source fixing device of the backlight module.

16, The backlight module of claim 10, wherein the LED lamp source fixing device of said backlight module is an aluminum extrusion; said heatsink plate comes into contact with said aluminum extrusion.

17, An LCD device, comprising: the backlight module of claim 9; said backlight module comprises a backplane; said backplane comprises a heatsink plate and a supporting plate connected with the heatsink plate; the heat conductivity of said heatsink plate is larger than the heat conductivity of said supporting plate.

18, The LCD device of claim 17, wherein, said heatsink plate and said supporting plate are both made of metal material.

19, The LCD device of claim 18, wherein, the shapes and the areas of said heatsink plate and said supporting plate keep consistent.

20, The LCD device of claim 17, wherein, said heatsink plate and said supporting plate are fixed in a mode of riveting or screw connection.

21, The LCD device of claim 17, wherein, said heatsink plate and said supporting plate are fixed in a mode of bonding by super glue.

22, The LCD device of claim 17, wherein said heatsink plate and said supporting plate are fixed in a mode of lock seaming; said heatsink plate and said supporting plate are folded in the joint to form clamping slots and clamping plates; the clamping plate of said heatsink plate is embedded into the clamping slot of said supporting plate; meanwhile, the clamping plate of said supporting plate is also embedded into the clamping slot of said heatsink plate to form said lock seaming connection.

23, The LCD device of claim 17, wherein, said heatsink plate is arranged in the area of an LED lamp source fixing device of the backlight module.

24, The LCD device of claim 18, wherein, the LED lamp source fixing device of said backlight module is an aluminum extrusion; said heatsink plate comes into contact with said aluminum extrusion.
